(19) United States
(12) Patent Application Publication
(10) Pub. No.: US 2009/0194167 A1
(43) Pub. Date: Aug. 6, 2009

(54) Methods of Forming Photoactive Layer

(75) Inventor: Christoph Brabec, Linz (AT)

Correspondence Address: FISH & RICHARDSON PC, P.O. BOX 1022, MINNEAPOLIS, MN, 55440-1022, US

(73) Assignee: Konarka Technologies, Inc., Lowell, MA (US)

(21) Appl. No.: 12/359,779

(22) Filed: Jan. 26, 2009

Related U.S. Application Data
(60) Provisional application No. 61/026,212, filed on Feb. 5, 2008.

(51) Int. Cl. H01L 31/00; H01L 51/48

(52) U.S. Cl. 136/261; 438/82; 257/E51.012

(57) ABSTRACT

Methods of forming a photoactive layer, as well as related compositions, photovoltaic cells, and photovoltaic modules, are disclosed.

### CROSS REFERENCE TO RELATED APPLICATION

Pursuant to 35 U.S.C. §119(e), this application claims priority to U.S. Provisional Application Ser. No. 61/026,212, filed Feb. 5, 2008, the contents of which are hereby incorporated by reference.

### TECHNICAL FIELD

This disclosure relates to methods of forming a photoactive layer, as well as related compositions, photovoltaic cells, and photovoltaic modules.

### BACKGROUND

Photovoltaic cells are commonly used to transfer energy in the form of light into energy in the form of electricity. A typical photovoltaic cell includes a photoactive material disposed between two electrodes. Generally, light passes through one or both of the electrodes to interact with the photoactive material. As a result, the ability of one or both of the electrodes to transmit light (e.g., light at one or more wavelengths absorbed by a photoactive material) can limit the overall efficiency of a photovoltaic cell. In many photovoltaic cells, a film of semiconductive material (e.g., indium tin oxide) is used to form the electrode(s) through which light passes because, although the semiconductive material can have a lower electrical conductivity than electrically conductive materials, the semiconductive material can transmit more light than many electrically conductive materials.

### SUMMARY

This disclosure relates to methods of forming a photoactive layer, as well as related compositions, photovoltaic cells, and photovoltaic modules.

In one aspect, this disclosure features methods that include (1) applying a composition containing first and second materials on a substrate to form an intermediate layer supported by the substrate, (2) removing at least some of the second material from the intermediate layer to form a porous layer having pores; and (3) disposing a third material in at least some of the pores of the porous layer to form a photoactive layer. The first material is different from the second material.

In another aspect, this disclosure features articles that include first and second electrodes, and a photoactive layer between the first and second electrodes. The photoactive layer includes a first semiconductor material and a second semiconductor material different from the first semiconductor material. The first and second semiconductor materials do not both have a solubility of at least about 0.1 mg/ml in any solvent at about 25° C. The article is configured as a photovoltaic cell.

In another aspect, this disclosure features articles that include first and second electrodes, and a photoactive layer between the first and second electrodes. The photoactive layer includes first and second semiconductor materials. The second semiconductor material has a solubility of at most about 10 mg/ml in any solvent at about 25° C. The article is configured as a photovoltaic cell.

In another aspect, this disclosure features articles that include first and second electrodes, and a photoactive layer between the first and second electrodes. The photoactive layer includes first and second semiconductor materials selected from the group consisting of a water-soluble semiconductor polymer and an organic solvent-soluble fullerene, an organic solvent-soluble semiconductor polymer and a water-soluble fullerene, an organic solvent-soluble semiconductor polymer and a water-soluble semiconductor polymer, and an organic solvent-soluble semiconductor polymer and a fullerene or a carbon allotrope that is not soluble in any solvent; and the article is configured as a photovoltaic cell.

In still another aspect, this disclosure features methods that include (1) providing an intermediate layer including a first material and a second material different from the first material, (2) removing at least some of the second material from the intermediate layer to form a porous layer having pores, and (3) disposing a third material in at least some of the pores of the porous layer to form a photoactive layer.

Embodiments can include one or more of the following features.

In some embodiments, the first, second, or third material is a semiconductor material.

In some embodiments, the first material includes an electron donor material. In certain embodiments, the electron donor material is selected from the group consisting of polythiophenes, polyanilines, polycarbazoles, polyvinylcarbazoles, polyphenylenes, polyphenylvinylenes, polysilanes, polythienylenevinylenes, polyisothianaphthanenes, polycyclopentadithiophenes, polysilacyclopentadithiophenes, polycyclopentadithiazoles, polythiazolothiazoles, polythiazoles, polybenzothiadiazoles, poly(thiophene oxide)s, poly(cyclopentadithiophene oxide)s, polythiadiazoloquinoxaline, polybenzoisothiazole, polybenzothiazole, polythienothiophene, poly(thienothiophene oxide), polydithienothiophene, poly(dithienothiophene oxide)s, polyfluorenes, polytetrahydroisoindoles, and copolymers thereof. For example, the electron donor material can include polythiophenes (e.g., poly(3-hexylthiophene) (P3HT)), polycyclopentadithiophenes (e.g., poly(cyclopentadithiophene-co-benzothiadiazole)), or copolymers thereof.

In some embodiments, the second or third material includes an electron acceptor material. In certain embodiments, the electron acceptor material includes a material selected from the group consisting of fullerenes, inorganic nanoparticles, oxadiazoles, discotic liquid crystals, carbon nanorods, inorganic nanorods, polymers containing CN groups, polymers containing CF₃ groups, and combinations thereof.

In some embodiments, the pores have an average diameter of at least about 20 nm (e.g., at least about 100 nm).

In some embodiments, the second or third material includes an electron donor material. In such embodiments, the first material can include an electron acceptor material.

In some embodiments, the third material is different from the first and second materials.

In some embodiments, the composition further includes a processing additive. In certain embodiments, the processing additive is selected from the group consisting of an alkane substituted with halo, thiol, CN, or COOR, R being H or C₁-C₁₀ alkyl; a cyclopentadithiophene optionally substituted with C₁-C₁₀ alkyl; a fluorene optionally substituted with C₁-C₁₀ alkyl; a thiophene optionally substituted with C₁-C₁₀ alkyl; a benzothiadiazole optionally substituted with C₁-C₁₀ alkyl; a naphthalene optionally substituted with C₁-C₁₀ alkyl; and a 1,2,3,4-tetrahydronaphthalene optionally substituted with C₁-C₁₀ alkyl.

In some embodiments, the processing additive is an alkane substituted with Cl, Br, I, SH, CN, or COOCH₃. For example, the alkane can be a C₆-C₁₂ alkane (e.g., octane). In certain embodiments, the processing additive is 1,8-diiodooctane, 1,8-dibromooctane, 1,8-dithioloctane, 1,8-dicyanooctane, or 1,8-di(methoxycarbonyl)octane.

In some embodiments, the at least some of the second material is removed by contacting the intermediate layer with a solvent. In certain embodiments, the solvent includes a compound selected from the group consisting of an alkane substituted with halo, thiol, CN, or COOR, R being H or C₁-C₁₀ alkyl; a cyclopentadithiophene optionally substituted with C₁-C₁₀ alkyl; a fluorene optionally substituted with C₁-C₁₀ alkyl; a thiophene optionally substituted with C₁-C₁₀ alkyl; a benzothiadiazole optionally substituted with C₁-C₁₀ alkyl; a naphthalene optionally substituted with C₁-C₁₀ alkyl; and a 1,2,3,4-tetrahydronaphthalene optionally substituted with C₁-C₁₀ alkyl.

In some embodiments, the solvent includes an alkane substituted with Cl, Br, I, SH, CN, or COOCH₃. For example, the alkane can be a C₆-C₁₂ alkane (e.g., octane). In certain embodiments, the solvent is 1,8-diiodooctane, 1,8-dibromooctane, 1,8-dithioloctane, 1,8-dicyanooctane, or 1,8-di(methoxycarbonyl)-octane.

In some embodiments, the at least some of the second material is removed by applying a vacuum to the intermediate layer, heating the intermediate layer, or a combination thereof.

In some embodiments, the substrate includes a first electrode. In such embodiments, the methods can further include disposing a second electrode on the photoactive layer to form a photovoltaic cell.

In some embodiments, the first material and the third material (or the second semiconductor material in a photoactive layer) do not both have a solubility of at least about 0.1 mg/ml (e.g., at least about 1 mg/ml or at least about 10 mg/ml) in any solvent at about 25° C.

In some embodiments, the third material (or the second semiconductor material in a photoactive layer) has a solubility of at most about 10 mg/ml (e.g., at most about 1 mg/ml or at most about 0.1 mg/ml) in any solvent at about 25° C.

In some embodiments, the second semiconductor material in a photoactive layer includes a carbon nanotube or a carbon nanorod.

In some embodiments, the first semiconductor material in a photoactive layer includes a cross-linked material.

Embodiments can include one or more of the following advantages.

Without wishing to be bound by theory, it is believed that the intermediate layer described above can serve as a template to form a photoactive layer with a desired morphology by replacing one of the first and second semiconductor materials with a third semiconductor material.

Without wishing to be bound by theory, it is believed that one advantage of forming a photoactive layer through an intermediate layer with a desired morphology is that the morphology of the intermediate layer does not change substantially during any subsequent processes.

Without wishing to be bound by theory, it is believed that one advantage of the methods described above is that they allow the preparation of a heterojunction photoactive layer with a desired morphology even though the two semiconductor materials (e.g., two semiconductor materials that do not have sufficient solubility in a common solvent) contained in the photoactive layer would otherwise result in an unfavorable morphology.

Other features and advantages will be apparent from the description, drawings, and claims.

### DESCRIPTION OF DRAWINGS

FIG. 1 is a cross-sectional view of an embodiment of a photovoltaic cell.

FIG. 2 is a schematic of a system containing multiple photovoltaic cells electrically connected in series.

FIG. 3 is a schematic of a system containing multiple photovoltaic cells electrically connected in parallel.

Like reference symbols in the various drawings indicate like elements.

### DETAILED DESCRIPTION

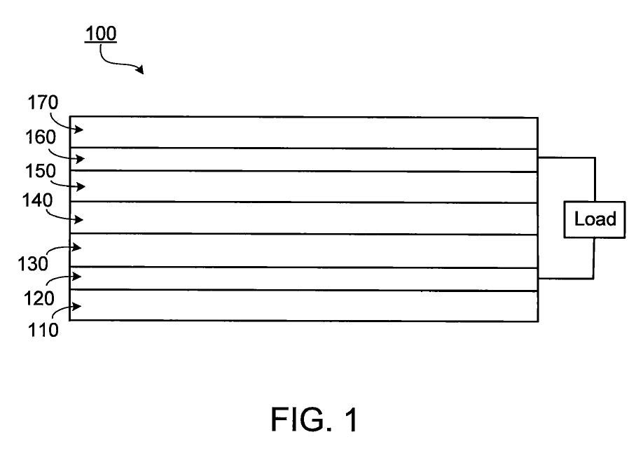

FIG. 1 shows a cross-sectional view of a photovoltaic cell 100 that includes a substrate 110, an electrode 120, a hole carrier layer 130, a photoactive layer 140, a hole blocking layer 150, an electrode 160, and a substrate 170. Electrodes 120 and 160 are electrically connected to an external load.

In some embodiments, photoactive layer 140 can be prepared by (1) applying a composition containing first and second materials on a substrate to form an intermediate layer supported by the substrate; (2) removing at least some of the second material from the intermediate layer to form a porous layer having pores; and (3) disposing a third material in at least some of the pores of the porous layer to form a photoactive layer. The first material is different from the second material. In certain embodiments, the third is different from the first and second materials. In some embodiments, the first, second, or third material is a semiconductor material.

In some embodiments, the first material can be an electron donor material (e.g., P3HT). In such embodiments, the second and third materials can be electron acceptor materials (e.g., C₆₁-PCBM or C₇₁-PCBM). In some embodiments, the first material can be an electron acceptor material. In such embodiments, the second and third materials can be electron donor materials. Additional exemplary electron donor materials and electron acceptor materials are described in more detail below.

The concentrations of the first and second materials in the composition can generally be adjusted as desired. For example, the composition can include at least about 0.5 wt % (e.g., at least about 0.7 wt %, at least about 0.8 wt %, at least about 0.9 wt %, or at least about 1.0 wt %) of the first material. As another example, the composition can include at least about 0.5 wt % (e.g., at least about 1.0 wt %, at least about 1.5wt %, at least about 2.0 wt %, at least about 2.5 wt %, at least about 3.0 wt %, or at least about 3.5 wt %) of the second material. In some embodiments, the concentrations can be adjusted to achieve a desired viscosity of the composition or a desired thickness of the layer to be formed.

In some embodiments, the weight ratio between the first and second materials can be at least about 0.5:1 (e.g., at least about 1:1, at least about 1.5:1, at least about 2:1, at least about 2.5:1, at least about 3:1, at least about 3.5: 1, at least about 4:1, at least about 4.5:1, or at least about 5:1).

In some embodiments, the composition further includes a solvent. For example, the solvent can be an organic solvent, such as chlorobenzene, o-dichlorobenzene, trichlorobenzene, o-xylene, m-xylene, p-xylene, toluene, mesitylene, ethylbenzene, isobutylbenzene, t-butylbenzene, α-methylnaphthalene, tetralin, N-methylpyrrolidone, methyl ethyl ketone, or acetone. In some embodiments, the solvent can be a mixture of the exemplary solvents mentioned above.

In some embodiments, the composition can be applied by a liquid-based coating process. The term “liquid-based coating process” mentioned herein refers to a process that uses a liquid-based coating composition. Examples of liquid-based coating compositions include solutions, dispersions, and suspensions.

The liquid-based coating process can be carried out by using at least one of the following processes: solution coating, ink jet printing, spin coating, dip coating, knife coating, bar coating, spray coating, roller coating, slot coating, gravure coating, flexographic printing, or screen printing. Without wishing to bound by theory, it is believed that the liquid-based coating process can be readily used in a continuous manufacturing process, such as a roll-to-roll process, thereby significantly reducing the cost of preparing a photovoltaic cell. Examples of roll-to-roll processes have been described in, for example, commonly-owned co-pending U.S. Application Publication No. 2005-0263179, the contents of which are hereby incorporated by reference.

The liquid-based coating process can be carried out at an elevated temperature (e.g., at least about 50° C., at least about 100° C., at least about 200° C., or at least about 300° C). The temperature can be adjusted depending on various factors, such as the coating process and the coating composition used. In some embodiments, when preparing a layer containing inorganic nanoparticles, the nanoparticles can be sintered at a high temperature (e.g., at least about 300° C.) to form interconnected nanoparticles. On the other hand, in certain embodiments, when a polymeric linking agent (e.g., poly(n-butyl titanate)) is added to the inorganic nanoparticles, the sintering process can be carried out at a lower temperature (e.g., below about 300° C.).

In some embodiments, when the composition contains organic first and second materials, the liquid-based coating process can be carried out by (1) dissolving or dispersing the first and second materials (e.g., P3HT and C₆₁-PCBM, respectively) in a suitable solvent (e.g., chlorobenzene) to form a solution or a dispersion, (2) coating the solution or dispersion on hole carrier layer 130, and (3) drying the coated solution or dispersion to form the intermediate layer.

In some embodiments, the composition can further include a processing additive (e.g., 1,8-diiodooctane or 1,8-dithioloctane). In some embodiments, the processing additive is selected from the group consisting of an alkane substituted with halo, thiol, CN, or COOR, R being H or C₁-C₁₀ alkyl; a cyclopentadithiophene optionally substituted with C₁-C₁₀ alkyl; a fluorene optionally substituted with C₁-C₁₀ alkyl; a thiophene optionally substituted with C₁-C₁₀ alkyl; a benzothiadiazole optionally substituted with C₁-C₁₀ alkyl; a naphthalene optionally substituted with C₁-C₁₀ alkyl; and a 1,2,3,4-tetrahydronaphthalene optionally substituted with C₁-C₁₀ alkyl. In certain embodiments, the processing additive is an alkane (e.g., a C₆-C₁₂ alkane such as an octane) substituted with Cl, Br, I, SH, CN, or COOCH₃. Examples of suitable processing additives have been described in, for example, commonly owned co-pending U.S. Application No. 60/984,229, the entire contents of which are hereby incorporated by reference.

Typically, the processing additive is removed during the drying of the coated solution. However, in some embodiments, at least some of the processing additive remains in the intermediate layer after the drying is complete. In such embodiments, the processing additives can be at least about 0.1 wt % (e.g., at least about 1 wt %, at least about 5 wt %, or at least about 10 wt %) of photoactive layer 140.

Without wishing to be bound by theory, it is believed that, in some embodiments, the processing additive substantially dissolves one of the first and second materials (e.g., C₆₁-PCBM), but does not substantially dissolve the other of the first and second materials (e.g., P3HT). As such, when the coating composition containing such a processing additive is applied to a surface to form an intermediate layer, the processing additive facilitates phase separation between the first and second materials so that an intermediate layer with a desirable morphology can be formed. Without wishing to be bound by theory, it is believed that the intermediate layer thus formed can serve as a template to form photoactive layer 140 with a desired morphology by replacing one of the first and second materials with a third material. Further, without wishing to be bound by theory, it is believed that one advantage of forming a photoactive layer through an intermediate layer with a desired morphology is that the morphology of the intermediate layer does not change substantially during any subsequent processes.

After the intermediate layer is formed, at least some of the second material can be removed from the intermediate layer to form a porous layer. In some embodiments, the removal can be carried out by contacting the intermediate layer with a suitable solvent (e.g., 1,8-diiodooctane or 1,8-dithioloctane) that substantially dissolves the second material, but does not substantially dissolve the first material. In general, the solvent can be either the same as or different from the processing additive described above.

In some embodiments, the removal can be carried out by applying a vacuum to the intermediate layer, heating the intermediate layer, or a combination thereof. For example, when the second material has a boiling point substantially lower than the first material, at least some of the second material can be removed by vacuum and/or heating (e.g., at a temperature well above the boiling of the second material but well below the boiling point of the first material) such that no significant amount of the first material is removed.

In some embodiments, the removal can be carried out during the drying of the intermediate layer, rather than after the intermediate layer is completely formed. For example, when the second material has a boiling point substantially lower than the first material, the removal can be carried out during drying at a temperature well above the boiling points of the solvent and the second material, but well below the boiling point of the first material. As such, at least some (e.g., all) of the second material is removed together with the solvent during drying to form a porous layer, while no significant amount of the first material is removed. In some embodiments, the drying is carried out under vacuum, either alone or in combination with heating.

In some embodiments, the first material can be cross-linked to form an insoluble material before or after removal of at least some of the second material. In some embodiments, the first material can include one or more cross-linkable groups (e.g., epoxy groups). In certain embodiments, the first material can include a fullerene substituted with one or more cross-linkable groups. Examples of such fullerenes have been described in commonly-owned co-pending U.S. Application Publication No. 2005-0279399, the contents of which are hereby incorporated by reference in its entirety. In certain embodiments, the first material can include an electron donor material (e.g., a polythiophene) substituted with one or more cross-linking groups. In some embodiments, the cross-linking can be carried out by subjecting the first material to an elevated temperature, moisture, and/or UV illumination. In some embodiments, a cross-linking agent can be added to the composition used to form the intermediate layer to cross-link the first material. An example of such a cross-linking agent is SILQUEST (Harwick Standard Distribution Corporation, Akron, Ohio). Without wishing to be bound by theory, it is believed that cross-linking of the first material could result in a material that is insoluble in any solvent and therefore could maintain the morphology of the first material during any subsequent processes. In certain embodiments, the first material can be thermally treated to form an insoluble material before or after removal of at least some of the second material.

In some embodiments, pores in the porous layer can have an average diameter of at least about 20 nm (e.g., at least about 50 nm or at least about 100 nm) and/or at most about 500 nm (e.g., at most about 300 nm or at most about 200 nm).

Once the porous layer is formed, a third material can be disposed into at least some of the pores to form photovoltaic layer 140. In some embodiments, the third material can be disposed by a liquid-based coating process, such as one of the processes described above. In some embodiments, the third material and the first or second material remaining in the porous layer do not both have a solubility of at least about 0.1 mg/ml (e.g., at least about 0.5 mg/ml, or at least about 1 mg/ml, at least about 5 mg/ml, or at least about 10 mg/ml) in any solvent at about 25° C.

In some embodiments, the third material can be dissolved or dispersed in a suitable solvent to form a composition and then disposed into at least some of the pores. In certain embodiments, one or more additives can be added to facilitate the disposition of the composition into the pores, for example, by modifying its wetting properties (e.g., surface tension). Examples of such additives include TRITON X (Sigma-Aldrich, St. Louis, Mo.), SURFYNOL (Air Products and Chemicals, Inc., Allentown, Pa.), and DYNOL (Air Products and Chemicals, Inc., Allentown, Pa.). In some embodiments, a second solvent can be added to the composition to modify its wetting properties.

In some embodiments, the third material has a solubility of at most about 10 mg/ml (e.g., at most about 1 mg/ml or at most about 0.1 mg/ml) in any solvent at about 25° C. Examples of such materials include carbon nanotubes or carbon nanorods. In some embodiments, such materials can be dispersed in a suitable solvent and then disposed into at least some of the pores.

In some embodiments, photoactive layer 140 prepared by the methods described above can have at least two separated phases where at least one of the two phases has an average grain size of at least about 20 nm (e.g., at least about 50 nm or at least about 100 nm) and/or at most about 500 nm (e.g., at most about 300 nm or at most about 200 nm). Without wishing to be bound by theory, it is believed that a larger separated phase in a photoactive layer can enhance the power-conversion efficiency of the photovoltaic cell. Further, in some embodiments, the methods described above can reduce the need of post-processing (e.g., temperature annealing or solvent annealing) of photoactive layer 140.

Without wishing to be bound by theory, it is believed that one advantage of the methods described above is that they allow the preparation of a heterojunction photoactive layer with a desired morphology even though the two semiconductor materials (e.g., two semiconductor materials that do not have sufficient solubility in a common solvent) contained in the photoactive layer would otherwise result in an unfavorable morphology. Exemplary pairs of such two materials include a water-soluble semiconductor polymer (e.g., a water-soluble polythiophene) and an organic solvent-soluble fullerene (e.g., C₆₁-PCBM), an organic solvent-soluble semiconductor polymer (e.g., P3HT) and a water-soluble fullerene, an organic solvent-soluble semiconductor polymer and a water-soluble semiconductor polymer, and an organic solvent-soluble semiconductor polymer and a carbon allotrope (e.g., carbon nanotubes or carbon nanorods) that is not soluble in any solvent. Unless specified otherwise, the term “soluble” mentioned herein means that a material has a solubility of at least about 0.1 mg/ml at 25° C. in a solvent. Examples of water-soluble polymers include poly(2-(3-thienyloxy)ethanesulfonate), sodium poly(2-(4-methyl-3-thienyloxy)ethanesulfonate), and poly(2-methoxy-5-propyloxysulfonate-1,4-phenylenevinylene). Examples of organic solvent-soluble polymer are described below. Examples of water-soluble fullerenes include [11-(2,2-dimethyl-[60]fulleropyrolidin-1-yl)-undecyl]-trimethyl-ammonium and [6,6]-bis[2,4-bis(7-octanoicacid-1-oxy)formicacidbenzylester]-C61. Examples of organic solvent-soluble fullerenes include pristine C60, pristine C70, C₆₁-PCBM, or C₇₁-PCBM.

In general, first, second, or third material can be an electron acceptor material (e.g., an organic electron acceptor material) or an electron donor material (e.g., an organic electron donor material). In some embodiments, photoactive layer 140 formed by the methods described above contains at least an electron acceptor material and at least an electron donor material.

Examples of electron acceptor materials include fullerenes, inorganic nanoparticles, oxadiazoles, discotic liquid crystals, carbon nanorods, inorganic nanorods, polymers containing moieties capable of accepting electrons or forming stable anions (e.g., polymers containing CN groups or polymers containing CF₃ groups), and combinations thereof. In some embodiments, the electron acceptor material is a substituted fullerene (e.g., C₆₁-PCBM or C₇₁-PCBM). In some embodiments, the electron acceptor materials can include small molecule compounds. Examples of such small molecule electron acceptors include polycyclic aromatic hydrocarbons (e.g., perylene). In some embodiments, a combination of electron acceptor materials can be used in photoactive layer 140.

Examples of electron donor materials include conjugated polymers, such as polythiophenes, polyanilines, polycarbazoles, polyvinylcarbazoles, polyphenylenes, polyphenylvinylenes, polysilanes, polythienylenevinylenes, polyisothianaphthanenes, polycyclopentadithiophenes, polysilacyclopentadithiophenes, polycyclopentadithiazoles, polythiazolothiazoles, polythiazoles, polybenzothiadiazoles, poly(thiophene oxide)s, poly(cyclopentadithiophene oxide)s, polythiadiazoloquinoxalines, polybenzoisothiazoles, polybenzothiazoles, polythienothiophenes, poly(thienothiophene oxide)s, polydithienothiophenes, poly(dithienothiophene oxide)s, polyfluorenes, polytetrahydroisoindoles, and copolymers thereof. In some embodiments, the electron donor material can be polythiophenes (e.g.,P3HT), polycyclopentadithiophenes (e.g., poly(cyclopentadithiophene-co-benzothiadiazole)), and copolymers thereof. In some embodiments, the electron donor materials can include small molecule compounds. Examples of such small molecule electron donors include polycyclic aromatic hydrocarbons (e.g., phthalocyanines and porphyrins). In certain embodiments, a combination of electron donor materials can be used in photoactive layer 140.

In some embodiments, the electron donor materials or the electron acceptor materials can include a polymer having a first comonomer repeat unit and a second comonomer repeat unit different from the first comonomer repeat unit. The first comonomer repeat unit can include a cyclopentadithiophene moiety, a silacyclopentadithiophene moiety, a cyclopentadithiazole moiety, a thiazolothiazole moiety, a thiazole moiety, a benzothiadiazole moiety, a thiophene oxide moiety, a cyclopentadithiophene oxide moiety, a polythiadiazoloquinoxaline moiety, a benzoisothiazole moiety, a benzothiazole moiety, a thienothiophene moiety, a thienothiophene oxide moiety, a dithienothiophene moiety, a dithienothiophene oxide moiety, or a tetrahydroisoindoles moiety.

In some embodiments, the first comonomer repeat unit includes a cyclopentadithiophene moiety. In some embodiments, the cyclopentadithiophene moiety is substituted with at least one substituent selected from the group consisting of C₁-C₂₀ alkyl, C₁-C₂₀ alkoxy, C₃-C₂₀ cycloalkyl, C₁-C₂₀ heterocycloalkyl, aryl, heteroaryl, halo, CN, OR, C(O)R, C(O)OR, and SO₂R; R being H, C₁-C₂₀ alkyl, C₁-C₂₀ alkoxy, aryl, heteroaryl, C₃-C₂₀ cycloalkyl, or C₁-C₂₀heterocycloalkyl. For example, the cyclopentadithiophene moiety can be substituted with hexyl, 2-ethylhexyl, or 3,7-dimethyloctyl. In certain embodiments, the cyclopentadithiophene moiety is substituted at 4-position. In some embodiments, the first comonomer repeat unit can include a cyclopentadithiophene moiety of formula (1):

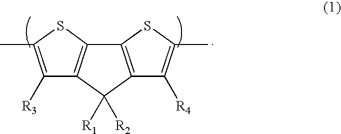

In formula (1), each of R₁, R₂, R₃, or R₄, independently, is H, C₁-C₂₀ alkyl, C₁-C₂₀ alkoxy, C₃-C₂₀ cycloalkyl, C₁-C₂₀ heterocycloalkyl, aryl, heteroaryl, halo, CN, OR, C(O)R, C(O)OR, or SO₂R; R being H, C₁-C₂₀ alkyl, C₁-C₂₀ alkoxy, aryl, heteroaryl, C₃-C₂₀ cycloalkyl, or C₁-C₂₀ heterocycloalkyl. For example, each of R₁ and R₂, independently, can be hexyl, 2-ethylhexyl, or 3,7-dimethyloctyl.

An alkyl can be saturated or unsaturated and branch or straight chained. A C₁-C₂₀ alkyl contains 1 to 20 carbon atoms (e.g., one, two, three, four, five, six, seven, eight, nine, 10, 11, 12, 13, 14, 15, 16, 17, 18, 19, and 20 carbon atoms). Examples of alkyl moieties include —CH₃, —CH₂—, —CH₂═CH₂—, —CH₂—CH═CH₂, and branched —C₃H₇. An alkoxy can be branch or straight chained and saturated or unsaturated. An C₁-C₂₀ alkoxy contains an oxygen radical and 1 to 20 carbon atoms (e.g., one, two, three, four, five, six, seven, eight, nine, 10, 11, 12, 13, 14, 15, 16, 17, 18, 19, and 20 carbon atoms). Examples of alkoxy moieties include —OCH₃ and —OCH═CH—CH₃. A cycloalkyl can be either saturated or unsaturated. A C₃-C₂₀ cycloalkyl contains 3 to 20 carbon atoms (e.g., three, four, five, six, seven, eight, nine, 10, 11, 12, 13, 14, 15, 16, 17, 18, 19, and 20 carbon atoms). Examples of cycloalkyl moieities include cyclohexyl and cyclohexen-3-yl. A heterocycloalkyl can also be either saturated or unsaturated. A C₃-C₂₀ heterocycloalkyl contains at least one ring heteroatom (e.g., O, N, and S) and 3 to 20 carbon atoms (e.g., three, four, five, six, seven, eight, nine, 10, 11, 12, 13, 14, 15, 16, 17, 18, 19, and 20 carbon atoms). Examples of heterocycloalkyl moieties include 4-tetrahydropyranyl and 4-pyranyl. An aryl can contain one or more aromatic rings. Examples of aryl moieties include phenyl, phenylene, naphthyl, naphthylene, pyrenyl, anthryl, and phenanthryl. A heteroaryl can contain one or more aromatic rings, at least one of which contains at least one ring heteroatom (e.g., O, N, and S). Examples of heteroaryl moieties include furyl, furylene, fluorenyl, pyrrolyl, thienyl, oxazolyl, imidazolyl, thiazolyl, pyridyl, pyrimidinyl, quinazolinyl, quinolyl, isoquinolyl, and indolyl.

Alkyl, alkoxy, cycloalkyl, heterocycloalkyl, aryl, and heteroaryl mentioned herein include both substituted and unsubstituted moieties, unless specified otherwise. Examples of substituents on cycloalkyl, heterocycloalkyl, aryl, and heteroaryl include C₁-C₂₀ alkyl, C₃-C₂₀ cycloalkyl, C₁-C₂₀ alkoxy, aryl, aryloxy, heteroaryl, heteroaryloxy, amino, C₁-C₁₀ alkylamino, C₁-C₂₀ dialkylamino, arylamino, diarylamino, hydroxyl, halogen, thio, C₁-C₁₀ alkylthio, arylthio, C₁-C₁₀ alkylsulfonyl, arylsulfonyl, cyano, nitro, acyl, acyloxy, carboxyl, and carboxylic ester. Examples of substituents on alkyl include all of the above-recited substituents except C₁-C₂₀ alkyl. Cycloalkyl, heterocycloalkyl, aryl, and heteroaryl also include fused groups.

The second comonomer repeat unit can include a benzothiadiazole moiety, a thiadiazoloquinoxaline moiety, a cyclopentadithiophene oxide moiety, a benzoisothiazole moiety, a benzothiazole moiety, a thiophene oxide moiety, a thienothiophene moiety, a thienothiophene oxide moiety, a dithienothiophene moiety, a dithienothiophene oxide moiety, a tetrahydroisoindole moiety, a fluorene moiety, a silole moiety, a cyclopentadithiophene moiety, a fluorenone moiety, a thiazole moiety, a selenophene moiety, a thiazolothiazole moiety, a cyclopentadithiazole moiety, a naphthothiadiazole moiety, a thienopyrazine moiety, a silacyclopentadithiophene moiety, an oxazole moiety, an imidazole moiety, a pyrimidine moiety, a benzoxazole moiety, or a benzimidazole moiety. In some embodiments, the second comonomer repeat unit is a 3,4-benzo-1,2,5-thiadiazole moiety.

In some embodiments, the second comonomer repeat unit can include a benzothiadiazole moiety of formula (2), a thiadiazoloquinoxaline moiety of formula (3), a cyclopentadithiophene dioxide moiety of formula (4), a cyclopentadithiophene monoxide moiety of formula (5), a benzoisothiazole moiety of formula (6), a benzothiazole moiety of formula (7), a thiophene dioxide moiety of formula (8), a cyclopentadithiophene dioxide moiety of formula (9), a cyclopentadithiophene tetraoxide moiety of formula (10), a thienothiophene moiety of formula (11), a thienothiophene tetraoxide moiety of formula (12), a dithienothiophene moiety of formula (13), a dithienothiophene dioxide moiety of formula (14), a dithienothiophene tetraoxide moiety of formula (15), a tetrahydroisoindole moiety of formula (16), a thienothiophene dioxide moiety of formula (17), a dithienothiophene dioxide moiety of formula (18), a fluorene moiety of formula (19), a silole moiety of formula (20), a cyclopentadithiophene moiety of formula (21), a fluorenone moiety of formula (22), a thiazole moiety of formula (23), a selenophene moiety of formula (24), a thiazolothiazole moiety of formula (25), a cyclopentadithiazole moiety of formula (26), a naphthothiadiazole moiety of formula (27), a thienopyrazine moiety of formula (28), a silacyclopentadithiophene moiety of formula (29), an oxazole moiety of formula (30), an imidazole moiety of formula (31), a pyrimidine moiety of formula (32), a benzoxazole moiety of formula (33), or a benzimidazole moiety of formula (34):

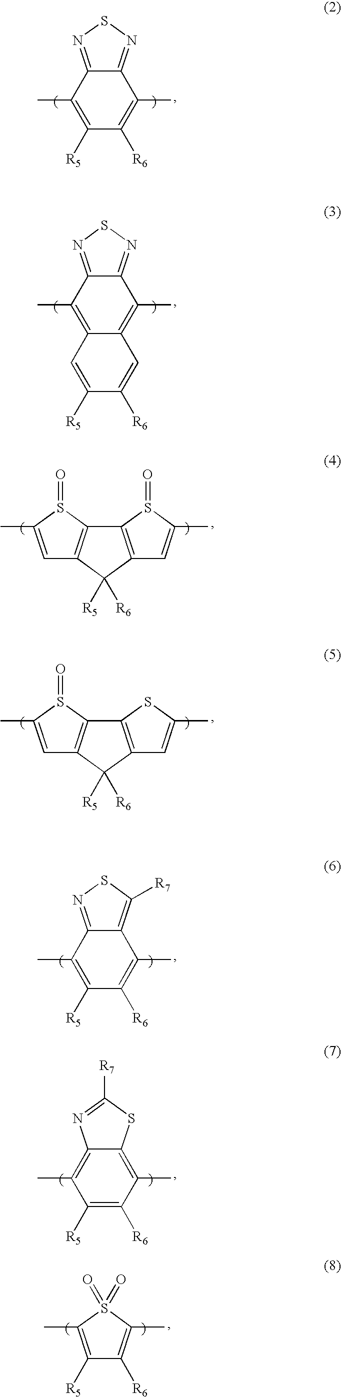

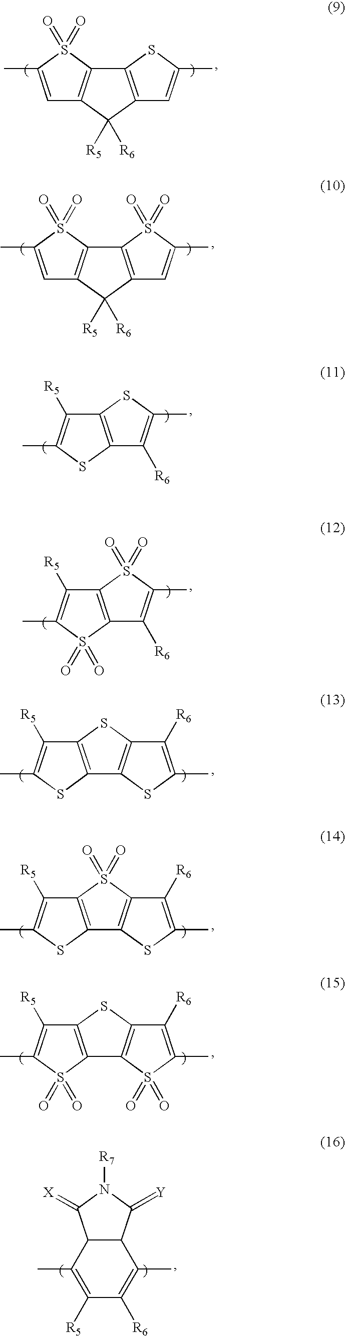

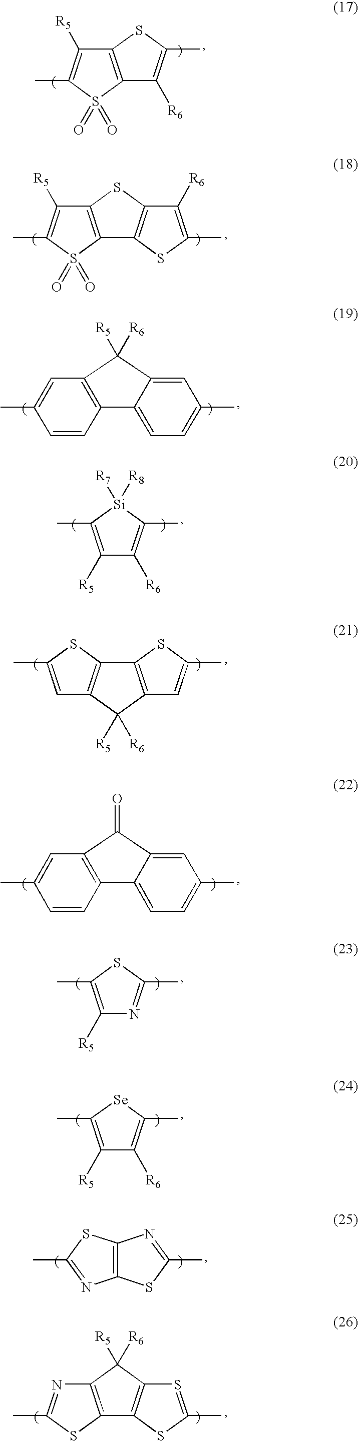

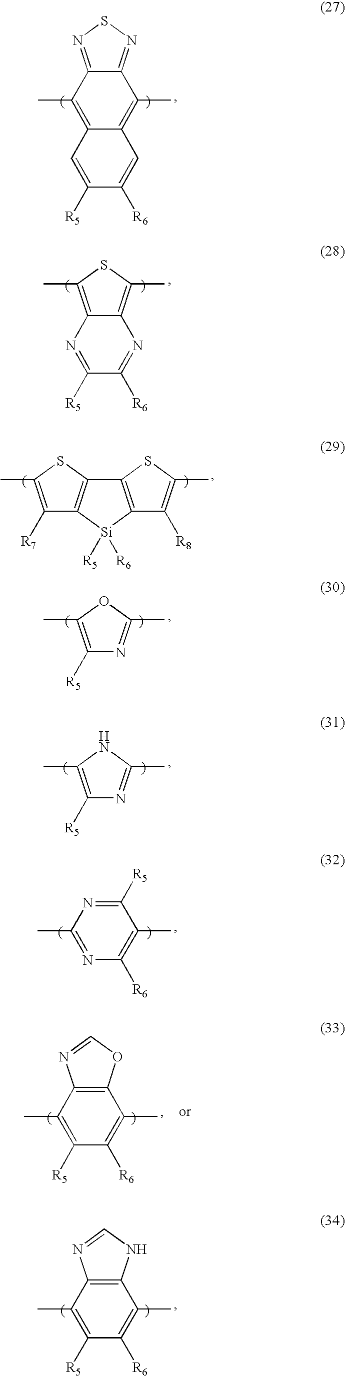

In the above formulas, each of X and Y, independently, is CH₂, O, or S; each of R₅ and R₆, independently, is H, C₁-C₂₀ alkyl, C₁-C₂₀ alkoxy, C₃-C₂₀ cycloalkyl, C₁-C₂₀ heterocycloalkyl, aryl, heteroaryl, halo, CN, OR, C(O)R, C(O)OR, or SO₂R, in which R is H, C₁-C₂₀ alkyl, C₁-C₂₀ alkoxy, aryl, heteroaryl, C₃-C₂₀ cycloalkyl, or C₁-C₂₀ heterocycloalkyl; and each of R₇ and R₈, independently, is H, C₁-C₂₀ alkyl, C₁-C₂₀ alkoxy, aryl, heteroaryl, C₃-C₂₀ cycloalkyl, or C₃-C₂₀ heterocycloalkyl. In some embodiments, the second comonomer repeat unit includes a benzothiadiazole moiety of formula (2), in which each of R₅ and R₆ is H.

The second comonomer repeat unit can include at least three thiophene moieties. In some embodiments, at least one of the thiophene moieties is substituted with at least one substituent selected from the group consisting of C₁-C₂₀ alkyl, C₁-C₂₀ alkoxy, aryl, heteroaryl, C₃-C₂₀ cycloalkyl, and C₃-C₂₀ heterocycloalkyl. In certain embodiments, the second comonomer repeat unit includes five thiophene moieties.

The polymer can further include a third comonomer repeat unit that contains a thiophene moiety or a fluorene moiety. In some embodiments, the thiophene or fluorene moiety is substituted with at least one substituent selected from the group consisting of C₁-C₂₀ alkyl, C₁-C₂₀ alkoxy, aryl, heteroaryl, C₃-C₂₀ cycloalkyl, and C₃-C₂₀ heterocycloalkyl.

In some embodiments, the polymer can be formed by any combination of the first, second, and third comonomer repeat units. In certain embodiments, the polymer can be a homopolymer containing any of the first, second, and third comonomer repeat units.

In some embodiments, the polymer can be

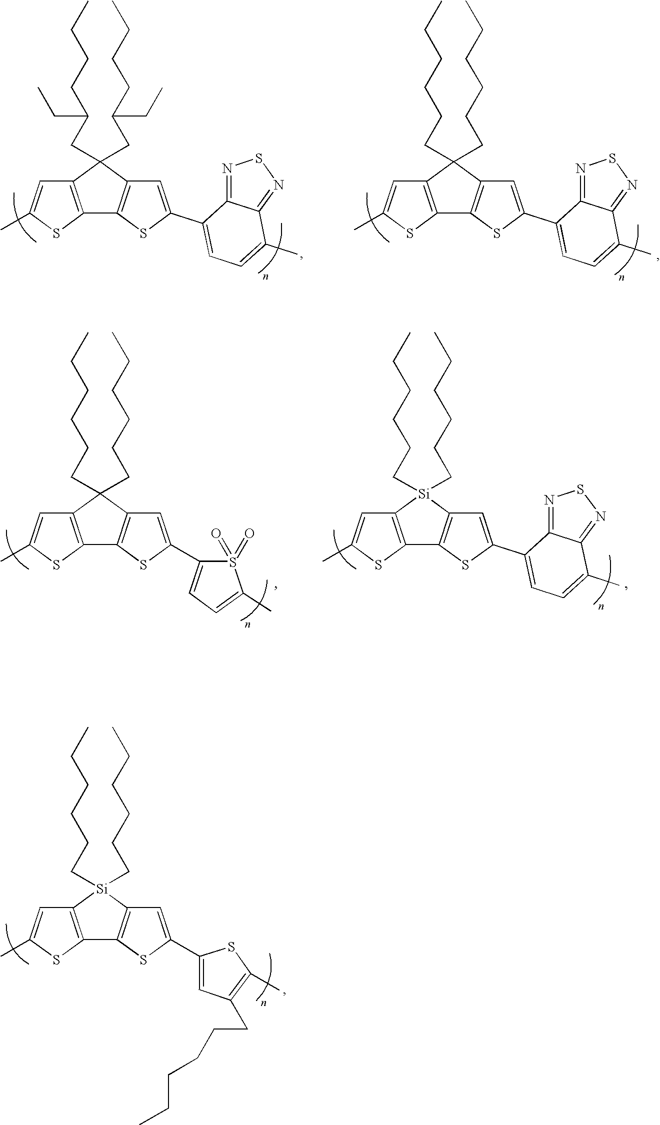

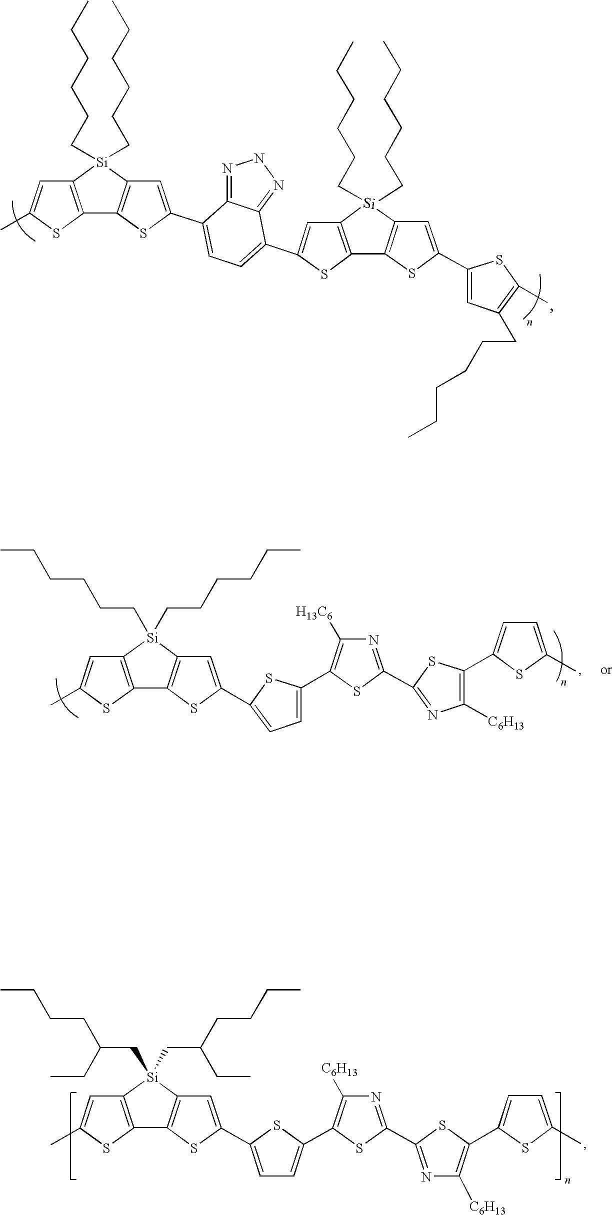

n which n can be an integer greater than 1.

In some embodiments, the electron donor or acceptor material can include a polymer containing at least one of the following two moieties:

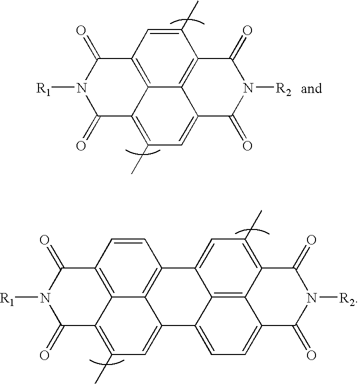

For example, the polymer can be

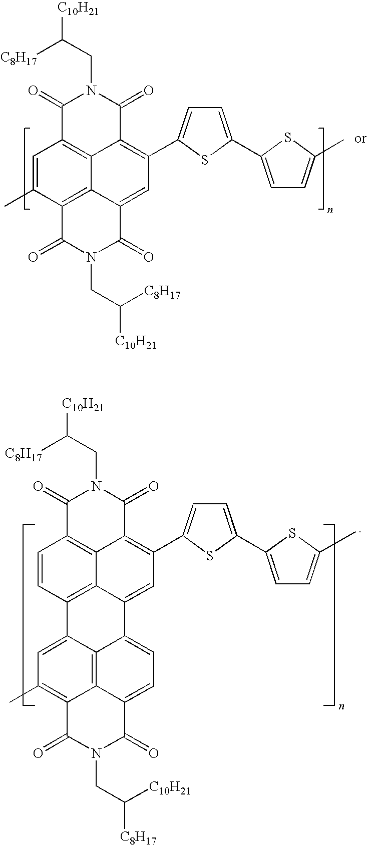

The monomers for preparing the polymers mentioned herein may contain a non-aromatic double bond and one or more asymmetric centers. Thus, they can occur as racemates and racemic mixtures, single enantiomers, individual diastereomers, diastereomeric mixtures, and cis- or trans- isomeric forms. All such isomeric forms are contemplated.

The polymers described above can be prepared by methods known in the art, such as those described in commonly owned co-pending U.S. application Ser. No. 11/601,374, the contents of which are hereby incorporated by reference. For example, a copolymer can be prepared by a cross-coupling reaction between one or more comonomers containing two alkylstannyl groups and one or more comonomers containing two halo groups in the presence of a transition metal catalyst. As another example, a copolymer can be prepared by a cross-coupling reaction between one or more comonomers containing two borate groups and one or more comonomers containing two halo groups in the presence of a transition metal catalyst. The comonomers can be prepared by the methods know in the art, such as those described in U.S. patent application Ser. No. 11/486,536, Coppo et al., Macromolecules 2003, 36, 2705-2711, and Kurt et al., J. Heterocycl. Chem. 1970, 6, 629, the contents of which are hereby incorporated by reference.

Without wishing to be bound by theory, it is believed that an advantage of the polymers described above is that their absorption wavelengths shift toward the red and near IR regions (e.g., 650-800 nm) of the electromagnetic spectrum, which is not accessible by most other conventional polymers. When such a polymer is incorporated into a photovoltaic cell together with a conventional polymer, it enables the cell to absorb the light in this region of the spectrum, thereby increasing the current and efficiency of the cell.

Generally, photoactive layer 140 is sufficiently thick to be relatively efficient at absorbing photons impinging thereon to form corresponding electrons and holes, and sufficiently thin to be relatively efficient at transporting the holes and electrons. In certain embodiments, photoactive layer 140 is at least 0.05 micron (e.g., at least about 0.1 micron, at least about 0.2 micron, at least about 0.3 micron) thick and/or at most about one micron (e.g., at most about 0.5 micron, at most about 0.4 micron) thick. In some embodiments, photoactive layer 140 is from about 0.1 micron to about 0.2 micron thick.

Turning to other components of photovoltaic cell 100, substrate 110 is generally formed of a transparent material. As referred to herein, a transparent material is a material which, at the thickness used in a photovoltaic cell 100, transmits at least about 60% (e.g., at least about 70%, at least about 75%, at least about 80%, at least about 85%) of incident light at a wavelength or a range of wavelengths used during operation of the photovoltaic cell. Exemplary materials from which substrate 110 can be formed include polyethylene terephthalates, polyimides, polyethylene naphthalates, polymeric hydrocarbons, cellulosic polymers, polycarbonates, polyamides, polyethers, and polyether ketones. In certain embodiments, the polymer can be a fluorinated polymer. In some embodiments, combinations of polymeric materials are used. In certain embodiments, different regions of substrate 110 can be formed of different materials.

In general, substrate 110 can be flexible, semi-rigid or rigid (e.g., glass). In some embodiments, substrate 110 has a flexural modulus of less than about 5,000 megaPascals (e.g., less than about 1,000 megaPascals or less than about 5,00 megaPascals). In certain embodiments, different regions of substrate 110 can be flexible, semi-rigid, or inflexible (e.g., one or more regions flexible and one or more different regions semi-rigid, one or more regions flexible and one or more different regions inflexible).

Typically, substrate 110 is at least about one micron (e.g., at least about five microns, at least about 10 microns) thick and/or at most about 1,000 microns (e.g., at most about 500 microns thick, at most about 300 microns thick, at most about 200 microns thick, at most about 100 microns, at most about 50 microns) thick.

Generally, substrate 110 can be colored or non-colored. In some embodiments, one or more portions of substrate 110 is/are colored while one or more different portions of substrate 110 is/are non-colored.

Substrate 110 can have one planar surface (e.g., the surface on which light impinges), two planar surfaces (e.g., the surface on which light impinges and the opposite surface), or no planar surfaces. A non-planar surface of substrate 110 can, for example, be curved or stepped. In some embodiments, a non-planar surface of substrate 110 is patterned (e.g., having patterned steps to form a Fresnel lens, a lenticular lens or a lenticular prism).

Electrode 120 is generally formed of an electrically conductive material. Exemplary electrically conductive materials include electrically conductive metals, electrically conductive alloys, electrically conductive polymers, and electrically conductive metal oxides. Exemplary electrically conductive metals include gold, silver, copper, aluminum, nickel, palladium, platinum, and titanium. Exemplary electrically conductive alloys include stainless steel (e.g., 332 stainless steel, 316 stainless steel), alloys of gold, alloys of silver, alloys of copper, alloys of aluminum, alloys of nickel, alloys of palladium, alloys of platinum and alloys of titanium. Exemplary electrically conducting polymers include polythiophenes (e.g., doped poly(3,4-ethylenedioxythiophene) (doped PEDOT)), polyanilines (e.g., doped polyanilines), polypyrroles (e.g., doped polypyrroles). Exemplary electrically conducting metal oxides include indium tin oxide, fluorinated tin oxide, tin oxide and zinc oxide. In some embodiments, combinations of electrically conductive materials are used.

In some embodiments, electrode 120 can include a mesh electrode. Examples of mesh electrodes are described in co-pending U.S. Patent Application Publication Nos. 20040187911 and 20060090791, the entire contents of which are hereby incorporated by reference.

Hole carrier layer 130 is generally formed of a material that, at the thickness used in photovoltaic cell 100, transports holes to electrode 120 and substantially blocks the transport of electrons to electrode 120. Examples of materials from which layer 130 can be formed include polythiophenes (e.g., PEDOT), polyanilines, polycarbazoles, polyvinylcarbazoles, polyphenylenes, polyphenylvinylenes, polysilanes, polythienylenevinylenes, polyisothianaphthanenes, and copolymers thereof. In some embodiments, hole carrier layer 130 can include combinations of hole carrier materials.

In general, the thickness of hole carrier layer 130 (i.e., the distance between the surface of hole carrier layer 130 in contact with photoactive layer 140 and the surface of electrode 120 in contact with hole carrier layer 130) can be varied as desired. Typically, the thickness of hole carrier layer 130 is at least 0.01 micron (e.g., at least about 0.05 micron, at least about 0.1 micron, at least about 0.2 micron, at least about 0.3 micron, or at least about 0.5 micron) and/or at most about five microns (e.g., at most about three microns, at most about two microns, or at most about one micron). In some embodiments, the thickness of hole carrier layer 130 is from about 0.01 micron to about 0.5 micron.

Optionally, photovoltaic cell 100 can include a hole blocking layer 150. The hole blocking layer is generally formed of a material that, at the thickness used in photovoltaic cell 100, transports electrons to electrode 160 and substantially blocks the transport of holes to electrode 160. Examples of materials from which the hole blocking layer can be formed include LiF, metal oxides (e.g., zinc oxide, titanium oxide), and amines (e.g., primary, secondary, or tertiary amines). Examples of amines suitable for use in a hole blocking layer have been described, for example, in co-pending U.S. Provisional Application Ser. No. 60/926,459, the entire contents of which are hereby incorporated by reference.

Without wishing to be bound by theory, it is believed that when photovoltaic cell 100 includes a hole blocking layer made of amines, the hole blocking layer can facilitate the formation of ohmic contact between photoactive layer 140 and electrode 160, thereby reducing damage to photovoltaic cell 100 resulted from such exposure.

Typically, hole blocking layer 150 is at least 0.02 micron (e.g., at least about 0.03 micron, at least about 0.04 micron, at least about 0.05 micron) thick and/or at most about 0.5 micron (e.g., at most about 0.4 micron, at most about 0.3 micron, at most about 0.2 micron, at most about 0.1 micron) thick.

Electrode 160 is generally formed of an electrically conductive material, such as one or more of the electrically conductive materials described above. In some embodiments, electrode 160 is formed of a combination of electrically conductive materials. In certain embodiments, electrode 160 can be formed of a mesh electrode.

In general, each of electrode 120, hole carrier layer 130, hole blocking layer 150, and electrode 160 can be prepared by a liquid-based coating process, such as one of the processes described above.

In some embodiments, when a layer (e.g., one of layers 120, 130, 150, and 160) includes inorganic semiconductor nanoparticles, the liquid-based coating process can be carried out by (1) mixing the nanoparticles with a solvent (e.g., an aqueous solvent or an anhydrous alcohol) to form a dispersion, (2) coating the dispersion onto a substrate, and (3) drying the coated dispersion. In certain embodiments, a liquid-based coating process for preparing a layer containing inorganic metal oxide nanoparticles can be carried out by (1) dispersing a precursor (e.g., a titanium salt) in a suitable solvent (e.g., an anhydrous alcohol) to form a dispersion, (2) coating the dispersion on a photoactive layer, (3) hydrolyzing the dispersion to form an inorganic semiconductor nanoparticles layer (e.g., a titanium oxide nanoparticles layer), and (4) drying the inorganic semiconductor material layer. In certain embodiments, the liquid-based coating process can be carried out by a sol-gel process.

In general, the liquid-based coating process used to prepare a layer containing an organic semiconductor material can be the same as or different from that used to prepare a layer containing an inorganic semiconductor material. In some embodiments, when a layer (e.g., one of layers 120, 130, 150, and 160) includes an organic semiconductor material, the liquid-based coating process can be carried out by mixing the organic semiconductor material with a solvent (e.g., an organic solvent) to form a solution or a dispersion, coating the solution or dispersion on a substrate, and drying the coated solution or dispersion.

Substrate 170 can be identical to or different from substrate 110. In some embodiments, substrate 170 can be formed of one or more suitable polymers, such as the polymers used in substrate 110 described above.

In general, during use, light can impinge on the surface of substrate 110, and pass through substrate 110, electrode 120, and hole carrier layer 130. The light then interacts with photoactive layer 140, causing electrons to be transferred from an electron donor material to an electron acceptor material. The electron acceptor material then transmits the electrons through intermediate layer 150 to electrode 160, and the electron donor material transfers holes through hole carrier layer 130 to electrode 120. Electrode 160 and electrode 120 are in electrical connection via an external load so that electrons pass from electrode 160, through the load, and to electrode 120.

While certain embodiments have been disclosed, other embodiments are also possible.

In some embodiments, photovoltaic cell 100 includes a cathode as a bottom electrode and an anode as a top electrode. In some embodiments photovoltaic cell 100 can also include an anode as a bottom electrode and a cathode as a top electrode.

In some embodiments, photovoltaic cell 100 can include the layers shown in FIG. 1 in a reverse order. In other words, photovoltaic cell 100 can include these layers from the bottom to the top in the following sequence: a substrate 170, an electrode 160, a hole blocking layer 150, a photoactive layer 140, a hole carrier layer 130, an electrode 120, and a substrate 110.

While photovoltaic cells have been described above, in some embodiments, the compositions and methods described herein can be used in tandem photovoltaic cells. Examples of tandem photovoltaic cells have been described in, for example, commonly owned co-pending U.S. Application Publication No. 2007-0181179 and U.S. application Ser. No. 11/734,093, the entire contents of which are hereby incorporated by reference.

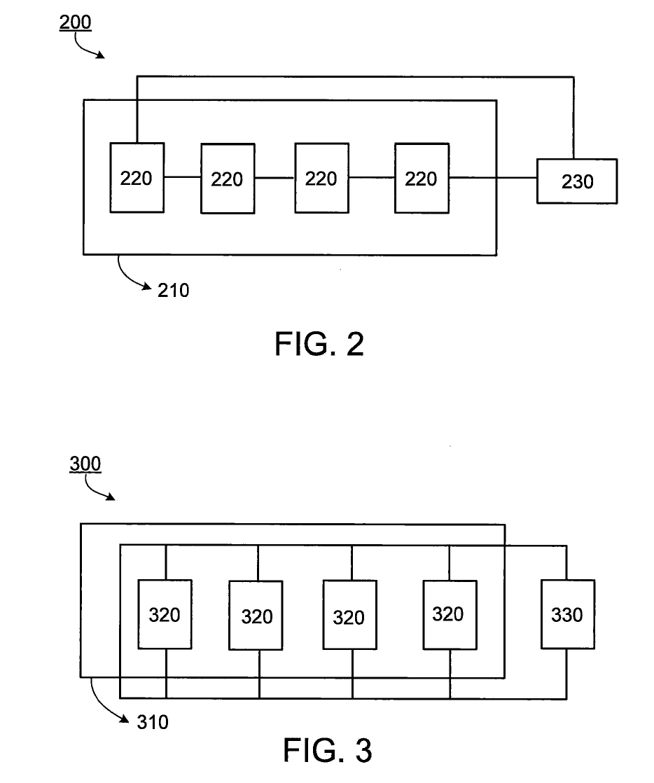

In some embodiments, multiple photovoltaic cells can be electrically connected to form a photovoltaic system. As an example, FIG. 2 is a schematic of a photovoltaic system 200 having a module 210 containing photovoltaic cells 220. Cells 220 are electrically connected in series, and system 200 is electrically connected to a load 230. As another example, FIG. 3 is a schematic of a photovoltaic system 300 having a module 310 that contains photovoltaic cells 320. Cells 320 are electrically connected in parallel, and system 300 is electrically connected to a load 330. In some embodiments, some (e.g., all) of the photovoltaic cells in a photovoltaic system can have one or more common substrates. In certain embodiments, some photovoltaic cells in a photovoltaic system are electrically connected in series, and some of the photovoltaic cells in the photovoltaic system are electrically connected in parallel.

While photovoltaic cells have been described above, in some embodiments, the compositions and methods described herein can be used to prepare a photoactive layer in other electronic devices and systems. For example, they can be used prepare a photoactive layer in suitable organic semiconductive devices, such as field effect transistors, photodetectors (e.g., IR detectors), photovoltaic detectors, imaging devices (e.g., RGB imaging devices for cameras or medical imaging systems), light emitting diodes (LEDs) (e.g., organic LEDs or IR or near IR LEDs), lasing devices, conversion layers (e.g., layers that convert visible emission into IR emission), amplifiers and emitters for telecommunication (e.g., dopants for fibers), storage elements (e.g., holographic storage elements), and electrochromic devices (e.g., electrochromic displays).

Other embodiments are in the claims.

What is claimed is:

1. A method, comprising:
applying a composition containing first and second materials on a substrate to form an intermediate layer supported by the substrate, the first material being different from the second material;
removing at least some of the second material from the intermediate layer to form a porous layer having pores; and
disposing a third material in at least some of the pores of the porous layer to form a photoactive layer.

2. The method of claim 1, wherein the first, second, or third material is a semiconductor material.

3. The method of claim 1, wherein the first material comprises an electron donor material.

4. The method of claim 3, wherein the electron donor material is selected from the group consisting of polythiophenes, polyanilines, polycarbazoles, polyvinylcarbazoles, polyphenylenes, polyphenylvinylenes, polysilanes, polythienylenevinylenes, polyisothianaphthanenes, polycyclopentadithiophenes, polysilacyclopentadithiophenes, polycyclopentadithiazoles, polythiazolothiazoles, polythiazoles, polybenzothiadiazoles, poly(thiophene oxide)s, poly(cyclopentadithiophene oxide)s, polythiadiazoloquinoxaline, polybenzoisothiazole, polybenzothiazole, polythienothiophene, poly(thienothiophene oxide), polydithienothiophene, poly(dithienothiophene oxide)s, polyfluorenes, polytetrahydroisoindoles, and copolymers thereof.

5. The method of claim 4, wherein the electron donor material comprises polythiophenes, polycyclopentadithiophenes, or copolymers thereof.

6. The method of claim 5, wherein the electron donor material comprises poly(3-hexylthiophene) or poly(cyclopentadithiophene-co-benzothiadiazole).

7. The method of claim 1, wherein the second or third material comprises an electron acceptor material.

8. The method of claim 7, wherein the electron acceptor material comprises a material selected from the group consisting of fullerenes, inorganic nanoparticles, oxadiazoles, discotic liquid crystals, carbon nanorods, inorganic nanorods, polymers containing CN groups, polymers containing CF₃ groups, and combinations thereof.

9. The method of claim 1, wherein the pores have an average diameter of at least about 20 nm.

10. The method of claim 1, wherein the pores have an average diameter of at least about 100 nm.

11. The method of claim 1, wherein the second or third material comprises an electron donor material.

12. The method of claim 11, wherein the first material comprises an electron acceptor material.

13. The method of claim 1, wherein the third material is different from the first and second materials.

14. The method of claim 1, wherein the composition further comprises a processing additive.

15. The method of claim 14, wherein the processing additive is selected from a group consisting of an alkane substituted with halo, thiol, CN, or COOR, R being H or C₁-C₁₀ alkyl; a cyclopentadithiophene optionally substituted with C₁-C₁₀ alkyl; a fluorene optionally substituted with C₁-C₁₀ alkyl; a thiophene optionally substituted with C₁-C₁₀ alkyl; a benzothiadiazole optionally substituted with C₁-C₁₀ alkyl; a naphthalene optionally substituted with C₁-C₁₀ alkyl; and a 1,2,3,4-tetrahydronaphthalene optionally substituted with C₁-C₁₀ alkyl.

16. The method of claim 15, wherein the processing additive is an alkane substituted with Cl, Br, I, SH, CN, or COOCH₃.

17. The method of claim 16, wherein the alkane is a C₆-C₁₂ alkane.

18. The method of claim 17, wherein the alkane is an octane.

19. The method of claim 18, wherein the processing additive is 1,8-diiodooctane, 1,8-dibromooctane, 1,8- dithioloctane, 1,8-dicyanooctane, or 1,8-di(methoxycarbonyl)octane.

20. The method of claim 1, wherein the at least some of the second material is removed by contacting the intermediate layer with a solvent.

21. The method of claim 20, wherein the solvent comprises a compound selected from a group consisting of an alkane substituted with halo, thiol, CN, or COOR, R being H or C₁-C₁₀ alkyl; a cyclopentadithiophene optionally substituted with C₁-C₁₀ alkyl; a fluorene optionally substituted with C₁-C₁₀ alkyl; a thiophene optionally substituted with C₁-C₁₀ alkyl; a benzothiadiazole optionally substituted with C₁-C₁₀ alkyl; a naphthalene optionally substituted with C₁-C₁₀ alkyl; and a 1,2,3,4-tetrahydronaphthalene optionally substituted with C₁-C₁₀ alkyl.

22. The method of claim 21, wherein the solvent comprises an alkane substituted with Cl, Br, I, SH, CN, or COOCH₃.

23. The method of claim 22, wherein the alkane is a C₆-C₁₂ alkane.

24. The method of claim 23, wherein the alkane is an octane.

25. The method of claim 24, wherein the solvent comprises 1,8-diiodooctane, 1,8-dibromooctane, 1,8-dithioloctane, 1,8-dicyanooctane, or 1,8-di(methoxycarbonyl)-octane.

26. The method of claim 1, wherein the at least some of the second material is removed by applying a vacuum to the intermediate layer, heating the intermediate layer, or a combination thereof.

27. The method of claim 1, wherein the substrate comprises a first electrode.

28. The method of claim 27, further comprising disposing a second electrode on the photoactive layer to form a photovoltaic cell.

29. The method of claim 1, wherein the first and third materials do not both have a solubility of at least about 0.1 mg/ml in any solvent at about 25° C.

30. The method of claim 1, wherein the third material has a solubility of at most about 1 mg/ml in any solvent at about 25° C.

31. An article, comprising:
first and second electrodes; and
a photoactive layer between the first and second electrodes, the photoactive layer comprising first and second semiconductor materials;
wherein the first and second semiconductor materials do not both have a solubility of at least about 0.1 mg/ml in any solvent at about 25° C., and the article is configured as a photovoltaic cell.

32. The article of claim 31, wherein the first and second semiconductor materials do not both have a solubility of at least about 1 mg/ml in any solvent at about 25° C.

33. The article of claim 31, wherein the first and second semiconductor materials do not both have a solubility of at least about 10 mg/ml in any solvent at about 25° C.

34. The article of claim 31, wherein the first semiconductor material is an electron donor material.

35. The article of claim 31, wherein the second semiconductor material is an electron acceptor material.

36. The article of claim 31, wherein the first semiconductor material comprises a cross-linked material.

37. An article, comprising:
first and second electrodes; and
a photoactive layer between the first and second electrodes, the photoactive layer comprising first and second semiconductor materials;
wherein the second semiconductor material has a solubility of at most about 10 mg/ml in any solvent at about 25° C., and the article is configured as a photovoltaic cell.

38. The article of claim 37, wherein the second semiconductor material has a solubility of at most about 1 mg/ml in any solvent at about 25° C.

39. The article of claim 37, wherein the second semiconductor material has a solubility of at most about 0.1 mg/ml in any solvent at about 25° C.

40. The article of claim 37, wherein the second semiconductor material comprises a carbon nanotube or a carbon nanorod.

41. An article, comprising:
first and second electrodes; and
a photoactive layer between the first and second electrodes, the photoactive layer comprising first and second semiconductor materials;
wherein the first and second semiconductor materials are selected from the group consisting of a water-soluble semiconductor polymer and an organic solvent-soluble fullerene, an organic solvent-soluble semiconductor polymer and a water-soluble fullerene, an organic solvent-soluble semiconductor polymer and a water-soluble semiconductor polymer, and an organic solvent-soluble semiconductor polymer and a fullerene or a carbon allotrope that is not soluble in any solvent; and the article is configured as a photovoltaic cell.

42. A method, comprising:
providing an intermediate layer comprising a first material and a second material different from the first material;
removing at least some of the second material from the intermediate layer to form a porous layer having pores; and
disposing a third material in at least some of the pores of the porous layer to form a photoactive layer.
